(19) United States
(12) Patent Application Publication
(10) Pub. No.: US 2019/0355876 A1
(43) Pub. Date: Nov. 21, 2019

(54) LIGHT EMITTING DIODE (LED) PACKAGE

(71) Applicant: DOMINANT Opto Technologies Sdn Bhd, Melaka (MY)

(72) Inventors: Tek Beng LOW, Melaka (MY); Eng Wah TAN, Melaka (MY); Chee Sheng LIM, Melaka (MY)

(73) Assignee: DOMINANT Opto Technologies Sdn Bhd, Melaka (MY)

(21) Appl. No.: 15/985,326

(22) Filed: May 21, 2018

(30) Foreign Application Priority Data
May 18, 2018 (MY) PI2018701914

(51) Int. Cl. H01L 33/48; H01L 33/62; H01L 33/52; H01L 25/075

(52) U.S. Cl. CPC H01L 33/483; H01L 33/62; H01L 2933/005; H01L 25/0753; H01L 2933/0066; H01L 33/52

(57) ABSTRACT

A light emitting diode (LED) package includes light emitting diode (LED) chips disposed within the package. Particularly, the light emitting diode (LED) chip is supported on a base, a light emitting window provide light emission surface to thelight emitting diode (LED) chip and a pair of leads electrically connected to the light emitting diode (LED) chip. The translucent housing of the light emitting diode (LED) chip has an elongated configuration for laterally enclosing each light emitting diode (LED) chip. The housing has at least a portion thereof forming a section having translucent properties.

### BACKGROUND OF THE INVENTION

### Field of the Invention

Embodiments of the present invention relate to optical device technologies, and more particularly, to light emitting diode (LED) package providing both side light emission and top light emission.

### Description of the Related Art

Since time immemorial when Thomas Edison came up with first electrical light bulb, various types of electrical lighting systems have been known and developed. Initially, most electrical lighting system existed to provide illumination to relatively dark areas. But significant developments occurred in the field of electrical lightening system in the 20th century, ranging from fluorescent lamps to incandescent lamp to sulfur lamps to Light Emitting Diode (LED).

Nick Hollnyak developed the first Light Emitting Diode (LED) in 1962. A Light Emitting Diode (LED) is defined as a semiconductor device that emits visible light when an electric current pass through it. When a suitable voltage is applied to the light emitting diode, electrons are able to recombine with electron holes within the device, releasing energy in the form of photons. This effect is known as electroluminescence and the color of the light emitted is determined by the energy gap of the semiconductor.

LEDs present many advantages over other light sources, including lower energy consumption, longer life, improved physical robustness, smaller size, and faster switching. LEDs have been used in numerous applications, as diverse as aviation lighting, digital microscopes, automotive lighting, decorative lighting assemblies, advertising, general lighting, and traffic signals. Their high switching rates are also useful in advanced communications technology.

Although LED technology has advanced and the diodes have become brighter, LED package available today is either top emitting (ie. Light emitted from the top) or side emitting (ie. Light emitted from the side). Both the side and top emitting packages have plastic or metal housing which does not let light through so that light is only emitted from the cavity/window.

CA2861157 discloses an LED based on the concept of varying the thickness of translucent housing to control the percentage of light transmission but emits light from one axis only.

There remains a need in the art to develop LED package which is able to provide both side light emission and top light emission. Accordingly, the present invention discloses an LED package which can provide both side and top light emission i.e emits light from more than one axis. The LED package disclosed in the present invention includes a side emitting package with translucent housing whereby the primary light is emitted from the side and the secondary light is emitted from the translucent housing. Moreover, the top emitting package of the LED has a translucent housing whereby the primary light is emitted from the top and the secondary light is emitted from the translucent housing.

### SUMMARY OF THE INVENTION

Various embodiments of the present disclosure relate to an LED package which can provide both side and top light emission.

More particularly, the embodiments of present invention relate to a light emitting diode (LED) package includes one or more light emitting diode (LED) chips disposed within the package. Particularly, one or more light emitting diode (LED) chips is supported on a base. Moreover, the light emitting diode (LED) chip is electrically connected to a lead frame and a printed circuit board (PCB) having a conductive pattern formed on a surface thereof facing the lead frame. The package also has a pair of leads electrically connected to the light emitting diode (LED) chip and the leads are positioned inside the translucent housing.

Furthermore, the pair of leads provides electrically conductive contact for flow of electricity into the light emitting diode (LED) package. The package also has a light emitting window to provide light emission surface to the light emitting diode (LED) chip. Particularly, the light emitting window is a top light emitting window. Moreover, translucent housing have an elongated configuration for laterally enclosing each light emitting diode (LED) chip. Particularly, the housing is having one or more portions thereof forming a section having translucent properties.

In accordance to various embodiment of present invention, the light emitting diode (LED) package is any one of a side emitting package, a top emitting package or combination thereof. Moreover, the light emitting diode (LED) chip have one or more surface portions for providing light emission pattern other than the light emitting window.

Various embodiments of present invention relate to various light emission patterns. Particularly, the light emission pattern includes a primary light pattern and a secondary light pattern. Moreover, emission pattern of light in the top emitting package includes emission of the primary light pattern from the light emitting window and emission of the secondary light from the translucent housing. Furthermore, emission pattern of light in the side emitting package includes emission of the primary light pattern from side and emission of the secondary light from the translucent housing. Subsequently, the light emission pattern is emitted in any one of an axial direction and a lateral direction.

In one embodiment, the light emitting diode (LED) package is of varied thickness. Particularly, the thickness of the translucent section of the translucent housing is varied. Moreover, the variation in thickness is to control a relative percentage ratio of light transmissions through the top light emitting window vs the translucent housing. Furthermore, size and shape of the light emitting diode (LED) package is contoured according to translucent housing to provide illumination. Moreover, translucent section of the light emitting diode (LED) package has multiple doping concentrations to provide and control relative light transmittance percentage ratio through top light emitting window.

According to various embodiments of present invention the light emitting diode (LED) chip, the lead frame and the printed circuit board (PCB) are positioned either within and/or adjacent to the translucent housing.

In one embodiment, the present invention also relates to a method of manufacturing a light assembly which is adapted for use as an LED-based source of light for utilitarian and/or decorative purposes. The light assembly includes one or more light emitting diode (LED) chips disposed within the package. Particularly, the one or more light emitting diode (LED) chips is supported on a base. Moreover, a pair of leads is electrically connected to the light emitting diode (LED) chip to provide electrically conductive contact for flow of electricity into the light emitting diode (LED) package.

Furthermore, the light emitting window provides light emission surface to the light emitting diode (LED) chip. Henceforth, a translucent housing having an elongated configuration for laterally enclosing each light emitting diode (LED) chip, and the housing is having at least a portion thereof forming a section having translucent properties.

In one embodiment, the method of manufacturing further includes pulling the light emitting diode (LED) chips through an extrusion of material which composes the translucent housing and constructing a combination of side emitting package and a top emitting package.

### BRIEF DESCRIPTION OF THE DRAWINGS

So that the above recited features of the present invention can be understood in detail, the invention will now be described with respect to the drawings. However, it is to be noted, that the scope of the invention is not limited to these drawings.

FIG. 1 is a two dimensional perspective view of Light Emitting Diode (LED) Package, in accordance with an embodiment of the present invention;

FIG. 2 is a front view of Light Emitting Diode (LED) Package, in accordance with an embodiment of the present invention;

FIG. 3 is a two dimensional back view of Light Emitting Diode (LED) Package, in accordance with an embodiment of the present invention;

FIG. 4 is a front and bottom view of Light Emitting Diode (LED) Package, in accordance with the invention;

FIG. 5 is a back and top view of Light Emitting Diode (LED) Package, in accordance with the invention;

FIG. 6 is a front and bottom view of Light Emitting Diode (LED) Package, in accordance with the invention; and

FIG. 7 is a front view of Light Emitting Diode (LED) Package, in accordance with the invention.

While the present invention of light emitting diode (LED) have been described herein by way of example for several embodiments and illustrative drawings, those skilled in the art will recognize that the present light emitting diode (LED) is not limited to embodiments or drawings described. It should be understood, that the drawings and detailed description thereto are not intended to limit embodiments to the particular form disclosed. Rather, the intention is to cover all modifications, equivalents and alternatives falling within the spirit and scope of the invention as defined by the appended claims.

Any headings used herein are for organizational purposes only and are not meant to limit the scope of the description or the claims. As used herein, the word “can” and “may” is used in a permissive sense (i.e., meaning having the potential to), rather than the mandatory sense (i.e., meaning must). Similarly, the words “include”,“including”, and “includes” mean including, but not limited to.

### Element List

Light Emitting Diode (LED) 100
Translucent Housing 105
Base 110
Pair of Leads 115
Light Emitting Diode (LED) Chip 120
Light Emitting Window 125
Side Emitting Package 400
Top emitting diode 500
Printed Circuit Board (PCB) (Not shown)
Lead Frame (Not shown)

### DETAILED DESCRIPTION

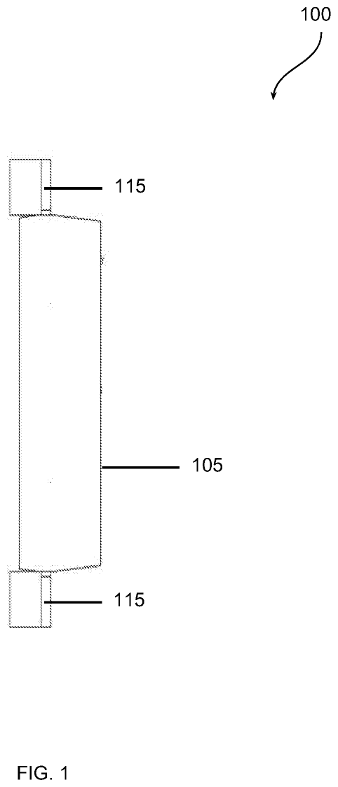

Various embodiments of the present invention relate to a Light Emitting Diode (LED) package which can provide both side and top light emission. The present invention uses a translucent housing which also lets light through from other than the main emitting cavity or window and emits light from more than one axis. Moreover, the principles of the present invention and their advantages are best understood by referring to FIG. 1 to FIG. 7.

In the following detailed description of illustrative or exemplary embodiments of the disclosure, specific embodiments in which the disclosure may be practiced are described in sufficient detail to enable those skilled in the art to practice the disclosed embodiments. For example, specific details such as specific method steps, structures, elements, and connections are presented herein. However, it is to be understood that the specific details presented need not be utilized to practice the embodiments of the present disclosure.

The following detailed description is, therefore, not to be taken in a limiting sense, and the scope of the present disclosure is defined by the appended claims and equivalents thereof. References within the specification to “one embodiment,” “an embodiment,” “embodiments,” or “one or more embodiments” are intended to indicate that a particular feature, structure, or characteristic described in connection with the embodiment is included in at least one embodiment of the present disclosure. The appearance of such phrases in various places within the specification are not necessarily all referring to the same embodiment, nor are separate or alternative embodiments mutually exclusive of other embodiments. Further, various features are described which may be exhibited by some embodiments and not by others. Similarly, various requirements are described which may be requirements for some embodiments but not other embodiments.

With reference now to the figures, particularly like reference numbers denote like parts, FIG. 1 is the two dimensional perspective view of Light Emitting Diode (LED) Package, in accordance with the invention. Particularly, the light emitting diode (LED) package 100, includes a pair of leads 115 and a translucent housing 105. Particularly, the pair of leads 115 are electrically connected to light emitting diode (LED) chip 120 to provide electrically conductive contact for flow of electricity into the light emitting diode (LED) package 100. Moreover, the emission pattern of light emitting diode (LED) package includes primary light pattern and a secondary light pattern. Furthermore, the pair of leads 115 is positioned inside the translucent housing 105.

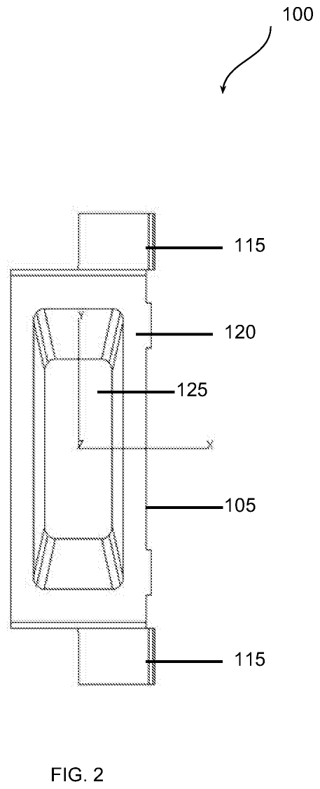

FIG. 2 is the front view of Light Emitting Diode (LED) Package, in accordance with the invention. The light emitting diode (LED) package 100 includes the pair of leads 115, multiple light emitting diode (LED) chips 120 disposed within the package 100. Particularly, the one or more light emitting diode (LED) chips 120 is supported on a base 110. Moreover, the light emitting diode (LED) chip 120 is electrically connected to a lead frame and a printed circuit board (PCB) having a conductive pattern formed on a surface thereof facing the lead frame. The package 100 also has the pair of leads 115 electrically connected to the light emitting diode (LED) chip 120 and the leads 115 are positioned inside the translucent housing 105. Furthermore, the pair of leads 115 provides electrically conductive contact for flow of electricity into the light emitting diode (LED) package 100. The package 100 also has a light emitting window 125 to provide light emission surface to the light emitting diode (LED) chip 120. Particularly, the light emitting window 125 is a top light emitting window. Moreover, the translucent housing 105 have an elongated configuration for laterally enclosing each light emitting diode (LED) chip 120. In particular, the housing 105 having one or more portions thereof forming a section having translucent properties.

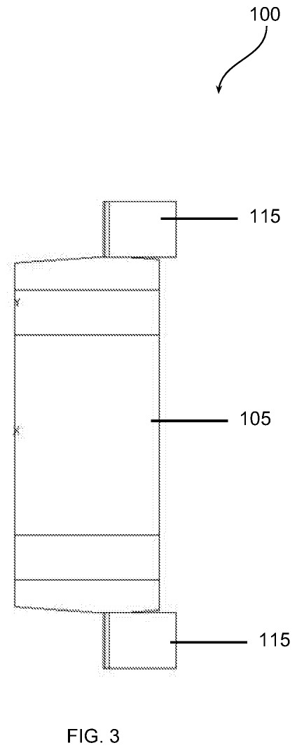

FIG. 3 is the two dimensional back view of Light Emitting Diode (LED) Package, in accordance with the present invention. The light emitting diode (LED) package 100 has translucent housing 105 with the pair of leads 115. Moreover, the size and shape of light emitting diode (LED) package 100 is contoured according to translucent housing 105 to provide illumination. The light emitting diode (LED) package is of varied thickness. Particularly, the thickness of the translucent section of the translucent housing 105 is varied. Moreover, the variation in thickness is to control a relative percentage ratio of light transmissions through the top light emitting window 125 vs the translucent housing 105. Subsequently, translucent section of the light emitting diode (LED) package 100 has multiple doping concentrations to provide and control relative light transmittance percentage ratio through top light emitting window 125. Furthermore, the size and shape of the light emitting diode (LED) package 100 is contoured according to translucent housing 105 to provide illumination.

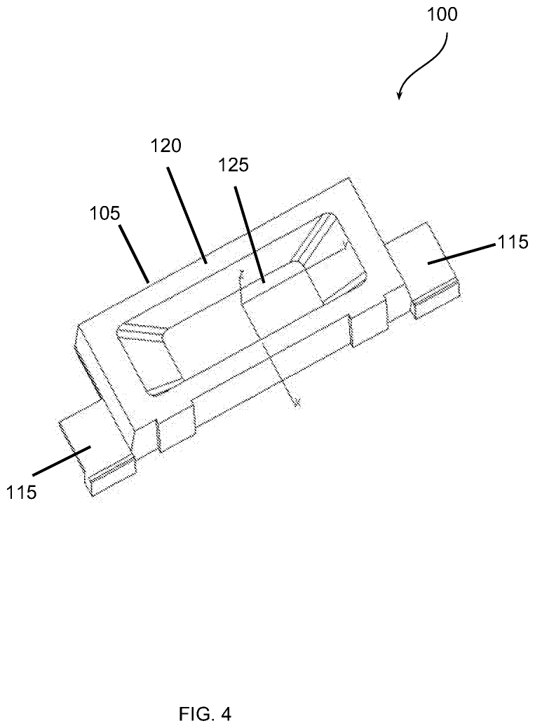

FIG. 4 is the front and bottom view of Light Emitting Diode (LED) Package, in accordance with the invention. Particularly, the light emitting diode (LED) chips 120 disposed within the package 400 and each light emitting diode (LED) chip 120 is supported on the base 110. Moreover, the top light emitting window 125 provides light emission surface to the light emitting diode (LED) chip 120. Further, the translucent housing 105 is having an elongated configuration for laterally enclosing each light emitting diode (LED) chip 120. Moreover, the light emitting diode (LED) chip 120 is manufactured through an extrusion of material which is composed of the translucent housing 125. Henceforth, the light emitting diode (LED) chip, the lead frame and the printed circuit board (PCB) are positioned either within and/or adjacent to the translucent housing 125.

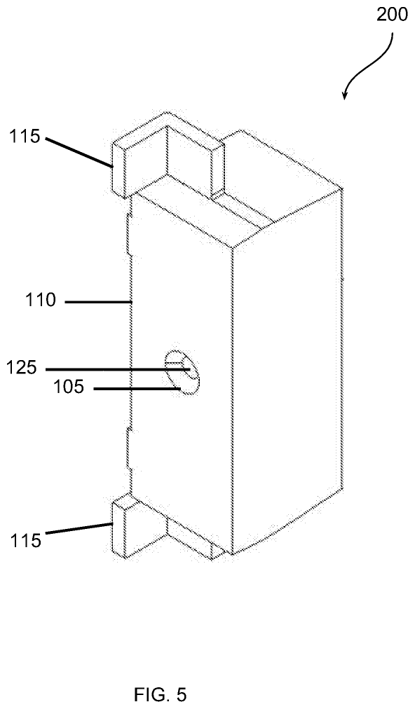

FIG. 5 is the back and top view of Light Emitting Diode (LED) Package, in accordance with the invention. Particularly, the light emitting diode (LED) package 100 is manufactured by pulling the light emitting diode (LED) chips 120 through an extrusion of material which includes the translucent housing 105 and constructing a combination of side emitting package 400 and the top emitting package 500. The light emitting diode (LED) package 100 is adapted for use as an LED-based source of light for utilitarian and/or decorative purposes. Moreover, the light emitting diode (LED) package 100 is a combination of a side emitting package 400 and the top emitting package 500. Henceforth, the emission pattern of light in top emitting package 500 includes emission of the primary light pattern from the light emitting window 125 and emission of secondary light from the translucent housing 105. Furthermore, the emission pattern of light in side emitting package 400 includes emission of primary light pattern from side and emission of secondary light from the translucent housing 105. Subsequently, light emission pattern is emitted in any one of an axial direction and a lateral direction.

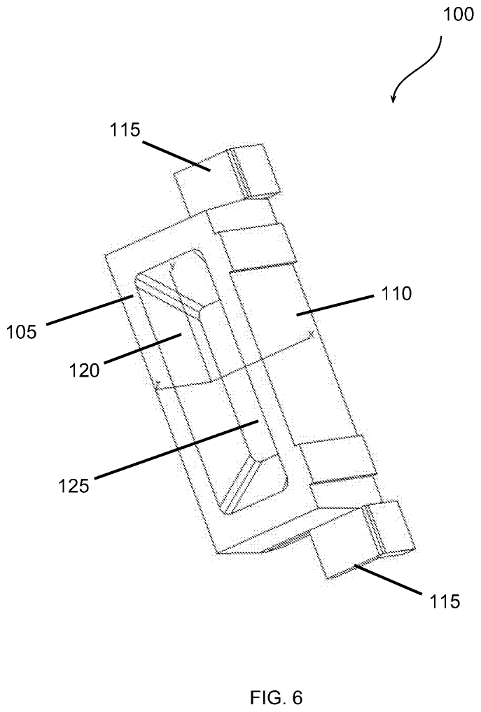

FIG. 6 is the front and bottom view of the light emitting diode (LED) package, in accordance with the invention. Particularly, the light emitting diode (LED) package 100 has light emitting diode (LED) chip 120 of light emitting diode (LED) package with one or more portions of surface for providing light emission pattern other than the light emitting window 125. Furthermore, the thickness of translucent section of the translucent housing 105 is varied in order to control the relative percentage ratio of light transmissions through the light emitting window 125 vs the translucent housing 105. Subsequently, translucent section of the light emitting diode (LED) package 100 has multiple doping concentrations to provide and control relative light transmittance percentage ratio through top light emitting window 125. Henceforth, the emission pattern of light emitting diode (LED) package 100 includes light emitted in axial direction and lateral direction.

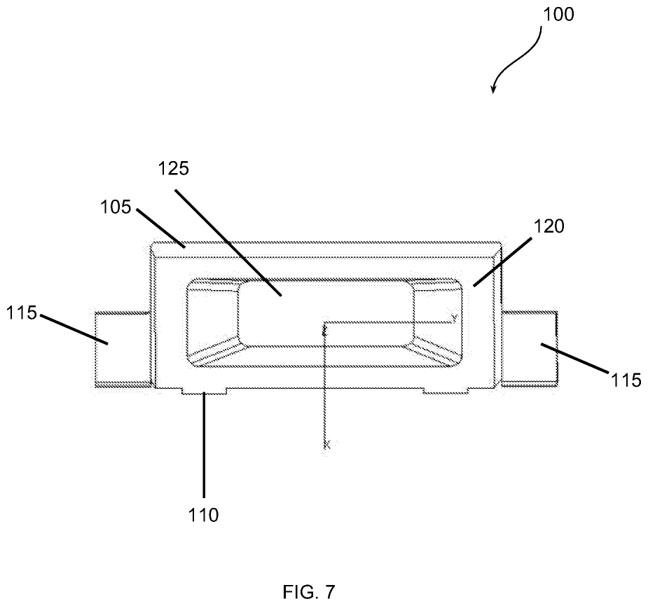

FIG. 7 is the front view of Light Emitting Diode (LED) Package, in accordance with the present invention. Particularly, the light emitting window 125 of the light emitting diode (LED) package is the top light emitting window 125. Moreover, the size and shape of light emitting diode (LED) package 100 is contoured according to translucent housing 105 to provide illumination with base 110 having the pair of leads 115, light emitting diode (LED) chips 120 and the light emitting window 125. Moreover, the pair of leads 115 is positioned inside the translucent housing 105. The light emitting diode (LED) package 100 is of varied thickness. Particularly, the thickness of the translucent section of the translucent housing 105 is varied. Moreover, the variation in thickness is to control a relative percentage ratio of light transmissions through the top light emitting window 125 vs the translucent housing 105. Furthermore, the size and shape of the light emitting diode (LED) package 100 is contoured according to translucent housing 105 to provide illumination.

In one embodiment of the present invention, the method of manufacturing a light assembly which is adapted for use as an LED-based source of light for utilitarian and/or decorative purposes includes pulling the one or more light emitting diode (LED) chip 120 through an extrusion of material which composes the translucent housing 105 and constructing a combination of the side emitting package 400 and the top emitting package 500.

Accordingly, in the present invention of LED package providing both side and top light emission has an advantage of emitting light from more than one axis. Furthermore, the translucent housing let light through the LED package and from the main emitting cavity or window. Particularly, the thickness of the translucent housing or the level of translucence can be varied in order to control the ratio of light emitted from the primary axis v/s through the secondary axis or from the primary window v/s through the translucent housing. Particularly, the present LED package includes the translucent housing and the primary window with varying thickness of the translucent housing and the level of translucence to control the ratio of light emitted from the primary window v/s through the translucent housing.

We claim:

1. A light emitting diode (LED) package, comprising:
at least one light emitting diode (LED) chip disposed within said package;a pair of leads electrically connected to said light emitting diode (LED) chip to provide electrical contact;
a light emitting window to provide light emission surface from said light emitting diode (LED) chip; and
a translucent housing for enclosing each light emitting diode (LED) chip having a plurality of light emitting properties,
wherein said housing having at least a portion thereof forming a section having said plurality of light emitting properties from at least one translucent surface.

2. The light emitting diode (LED) package of claim 1, wherein said light emitting diode (LED) package having at least one surface portion for providing light emission pattern other than said light emitting window.

3. The light emitting diode (LED) package of claim 2, wherein said light emission pattern comprises a primary light pattern and a secondary light pattern.

4. The light emitting diode (LED) package of claim 1, wherein said light emitting diode (LED) package is any one of a side emitting package, a top emitting package or combination thereof.

5. The light emitting diode (LED) package of claim 4, wherein emission pattern of light in said top emitting package comprises emission of said primary light pattern from said light emitting window and emission of said secondary light from said translucent housing.

6. The light emitting diode (LED) package of claim 3, wherein emission pattern of light in said side emitting package comprises emission of said primary light pattern from side and emission of said secondary light from said translucent housing.

7. The light emitting diode (LED) package of claim 1, wherein thickness of said translucent section of said translucent housing is varied in order to control a relative percentage ratio of light transmissions through said top light emitting window vs said translucent housing.

8. The light emitting diode (LED) package of claim 2, wherein said light emission pattern is emitted in any one of an axial direction and a lateral direction.

9. The light emitting diode (LED) package of claim 1, wherein said light emitting window is a top light emitting window.

10. The light emitting diode (LED) package of claim 1, wherein size and shape of said light emitting diode (LED) package is contoured according to translucent housing to provide illumination.

11. The light emitting diode (LED) package of claim 1, wherein said light emitting diode (LED) chip is electrically connected to a lead frame and a printed circuit board (PCB) having a conductive pattern formed on a surface thereof facing said lead frame.

12. The light emitting diode (LED) package of claim 1, wherein said pair of leads are positioned inside said translucent housing.

13. The light emitting diode (LED) package of claim 11, wherein said light emitting diode (LED) chip, said lead frame and said printed circuit board (PCB) are positioned either within and/or adjacent to said translucent housing.

14. A method of manufacturing a light assembly which is adapted for use as an LED-based source and said light assembly comprising:
at least one light emitting diode (LED) chip disposed within said package;
a pair of leads electrically connected to said light emitting diode (LED) chip to provide electrical contact;
a light emitting window to provide light emission surface from said light emitting diode (LED) chip;
a translucent housing for enclosing each light emitting diode (LED) chip, and wherein said housing having at least a portion thereof forming a section having translucent properties.

15. The method of manufacturing a light assembly of claim 14, wherein said method comprising:
pulling said at least one light emitting diode (LED) chip through an extrusion of material which composes said translucent housing; and
constructing a combination of a side emitting package and a top emitting package.

16. The method of manufacturing a light assembly of claim 14, wherein said light emitting window is a top light emitting window.

17. The light emitting diode (LED) package of claim 7, wherein said translucent section of said translucent housing has a plurality of doping concentration to provide and control a plurality of said relative light transmittance percentage ratio through said top light emitting window.
